(19) United States
(12) Patent Application Publication
(10) Pub. No.: US 2011/0006785 A1
(43) Pub. Date: Jan. 13, 2011

(54) ANALYZING METHOD USING A PROCESSING STRUCTURE AS A PROBE

(76) Inventor: Lubomir Gradinarsky, Molndal (SE)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/863,995

(22) PCT Filed: Jan. 20, 2009
(86) PCT No.: PCT/SE09/50051

§ 371 Date: Sep. 16, 2010

Related U.S. Application Data
(63) Continuation-in-part of application No. 61/022,547, filed on Jan. 22, 2008.

(51) Int. Cl. G01N 22/04; G01R 27/04; G01N 22/00; G06F 19/00

(52) U.S. Cl. 324/640; 324/639; 324/642; 700/112

(57) ABSTRACT

The invention relates to a method of analyzing a material contained inside a process vessel. An electromagnetic signal is applied to an elongated processing structure inside the vessel. The propagated electromagnetic signal is detected and information about dielectric properties of the material is extracted based on the detected signal. The invention also relates to a device comprising an elongated processing structure and a use of a processing structure.

### TECHNICAL FIELD

The present invention relates to a method of analysing a material contained inside a process vessel. The invention also relates to a method of controlling a manufacturing process and a manufacturing method. Furthermore, the invention relates to a device comprising a process vessel configured and dimensioned to contain material to be processed. Also, the invention relates to a use of a processing structure, which extends inside a process vessel.

### BACKGROUND OF THE INVENTION

Recently, the pharmaceutical industry has begun to look for alternatives to the traditionally used batch production. This is in order to improve production efficiency and time to market. Such new opportunities are presented by applying continuous production is methods e.g. continuous granulation. The continuous production in the pharmaceutical industry avoids the need for scale-up, thereby reducing equipment purchasing and also saving on the time for transfer of the production methods from development to operations. Using continuous processing also allows for more flexible control of the production volumes. Other advantages are easier to automate, less material handling and lower risk of losing material due to quality problems. Due to the fact that continuous granulation cannot rely on testing at the end of each production step in order to ensure the end-product quality, usage of Process Analytical Technology (PAT) during the production is highly desirable. Pharmaceutical equipment and processes which are good candidates for the continuous approach are e.g. continuous granulators (mixers where water is added along the vessel structure), mixers, extruders, fluidized beds, where the processes being: continuous granulation, mixing, transport from vessel to vessel, fluidized bed granulation, coating, drying. Process control is highly desirable.

### SUMMARY OF THE INVENTION

An object of the present invention is to provide a method of analysing a material contained inside a process vessel, which method may suitably be applied in, although not limited to, a continuous manufacturing process. This and other objects, which will become apparent in the following, are achieved by the invention as defined in the accompanying claims.

The present invention is based on the insight that elongated processing structures that extend inside process vessels may be provided with additional functionality. In particular, the elongated processing structures may be used for propagating an electromagnetic signal, which can be analysed to provide information about properties of the material in the vicinity of said elongated processing structure.

According to at least one aspect of the invention, a method of analysing a material contained inside a process vessel is provided, the process vessel having an elongated processing structure extending inside the vessel for processing the material. The method comprises:

applying an electromagnetic signal to the processing structure so that the electromagnetic signal is propagated along the processing structure,

detecting the propagated electromagnetic signal,

determining a value related to the detected signal, and

extracting information about dielectric properties of the material or physical parameters affecting the dielectric properties of the material based on the determined value of the detected signal.

Thus, the elongated processing structure, which is adapted to perform a given processing function, also serves as a carrier of the electromagnetic signal. The electromagnetic signal may be applied while the processing structure performs its standard function, or alternatively, the electromagnetic signal may be applied before and/or after the standard processing function is performed.

The general inventive idea of applying an electromagnetic signal to an elongated processing structure within a process vessel, may be implemented for various kinds of processing structures. For instance, the processing structure may be a mixing element, a transporting element, an extrusion element, etc. The processing structure may take the form of a rotating element, such as a screw, an impeller, or a tubular structure such as a gas flow conducting structure, etc. Some of the alternatives are presented in the example embodiments below.

Thus, according to at least one example embodiment of the invention, the method comprises rotating the elongated processing structure around a longitudinal geometrical axis for mixing material inside the vessel, transporting material through the vessel, or extruding material from the vessel. Thus, it may, for example, be in the form of a shaft or mixing screw in a continuous granulation process. The screw may be allowed to rotate while the electromagnetic signal is applied. Alternatively, an electromagnetic signal may, for calibration purposes, be applied before rotating the screw, and then another electromagnetic signal may be applied while or after rotating the screw.

According to at least one example embodiment of the invention, the method comprises conducting a gas flow through the processing structure in order to circulate the material inside the vessel. This may, for example, be in the form of a gas pipe for fluidising solid particles in a fluidised bed vessel. A fluidised bed vessel may be used for batch processes or for continuous processes in which an outlet of the vessel may be connected to the next processing equipment.

The propagated electromagnetic signal may during its travel be affected by its environment. For instance, discontinuities, moisture, temperature, density and density changes of the processed material will affect the signal. There are a number of alternatives for detecting such effects on the electromagnetic signal.

According to at least one example embodiment of the invention, the determined value represents a time of travel of the electromagnetic signal. For instance, discontinuities, such as air bubbles in the material, will result in a different time of travel compared to if the material would have been homogenous.

According to at least one example embodiment of the invention, the determined value represents a distortion of the applied electromagnetic signal. Such distortion may be a change of amplitude and a delay of the electromagnetic signal. These changes may be determined in a time domain analysis. Alternatively, a change of amplitude and phase of individual frequencies of the electromagnetic signal may be determined in a frequency domain analysis. In the frequency domain analyses a time series of spectra is created and the changes of frequencies over time will indicate the changes in the process state.

According to at least one example embodiment, the electromagnetic signal is detected after it has been reflected. The reflection (full or partial) may occur along the elongated structure or at the end of the elongated structure, e.g. due to a discontinuity of the material or change of medium. One control unit (or several) may be used both for transmitting the electromagnetic signal and receiving the reflected electromagnetic signal. A conceivable alternative would be to have one or more measurement points along the elongated structure, thereby enabling detection of non-reflected electromagnetic signals.

The electromagnetic signal may be applied in the form of an electromagnetic pulse. This may e.g. be in the form of a discrete pulse or in the form of a sudden increase/decrease of the signal voltage of a continuously applied signal.

Another alternative is that the electromagnetic signal may be applied in the form of a continuous electromagnetic wave having constant voltage amplitude. This may suitably be used for direct measurement, i.e. non-reflected signal, although the option of reflected signal measurement should not be excluded.

The extracted information about dielectric properties of the material may be used in obtaining information about any one of or any combination of the following physical parameters: discontinuities in the material (due to air gaps or material jams), moisture content of the material, temperature of the material, and density of the material. However, other information is also conceivable.

An alternative to measuring the dielectric properties of the material is to measure or estimate one or more of the above-mentioned physical parameters directly without going through the dielectric properties information. This may be achieved through modelling and calibration. For instance, if a number of different sets of material having known moisture contents are provided in the process vessel, the obtained response signal for each set of material, i.e. each moisture content, is registered. These registered response signals can then be used for comparison and estimation with response signals of later performed analyses of material having unknown moisture content.

Depending on the application, e.g. detection of powder discontinuity, density, moisture content, etc. different frequencies may be appropriate for the applied electromagnetic signal. The chosen frequency will also depend on the dimension of the process vessels, since certain frequencies could propagate better for certain geometries. However, in general, electromagnetic signals within the frequencies of 1 Hz to 100 GHz may suitably be used in the present invention, and may commonly be within the frequencies of 1 MHz to 10 GHz, which allows for elaborate analyses of the material properties.

The inventive method of analysing material contained inside a process vessel, including any example embodiments thereof, may suitably be included in a method of controlling a manufacturing process. The manufacturing process would then be controlled based on the extracted information about dielectric properties or other physical parameters, such as the moisture of the material. For instance, any one of or any combination of the following parameters may be controlled: temperature of the material, addition of liquid to the material, mixing time, rotational speed of the processing structure or gas flow through the processing structure.

Furthermore, the inventive method of analysing material contained inside a process vessel, including any example embodiments thereof, and the method of controlling a manufacturing process, may both suitably be included in a method of manufacturing a product, such as a pharmaceutical product. The method of manufacturing may comprise:

inserting material into a process vessel having a processing structure extending inside the vessel for processing the material,

processing the material inside the process vessel,

carrying out an analysis of material in accordance with the above-mentioned analysing,

controlling the processing of the material in accordance with the above-mentioned controlling method,

removing the processed material from the process vessel, and

providing the processed and removed material in the form of tablets or in the form of powder contained in either blisters, capsules, vials, ampules, sachets or inhalers.

According to a further aspect of the invention, a device is provided. The device comprises a process vessel configured and dimensioned to contain material to be processed. An elongated processing structure extends inside the process vessel for processing the material contained in the process vessel. A signal generator is operatively connected to the processing structure for applying an electromagnetic signal to the processing structure so that the electromagnetic signal is propagated along the processing structure. A detector for detecting the propagated electromagnetic signal is present, and also a control unit for determining a value related to the detected signal and for extracting information about dielectric properties of the material or physical parameters affecting the dielectric properties of the material based on the determined value of the detected signal.

The signal generator may be any suitable generator for providing an electromagnetic signal output. Suitably, the signal generator and the detector may be incorporated in one transmitter/receiver unit, such as said control unit. However, other alternative setups are also conceivable.

According to at least one example embodiment, the elongated processing structure is rotatable around a longitudinal geometrical axis for mixing material inside the vessel, transporting material through the vessel, or extruding material from the vessel. For instance, the elongated processing structure may comprise at least one elongated screw, which is configured to mix, transport and/or extrude the material. Said screw may be one of two elongated screws, whereby a potential difference is obtained between the two screws. Alternatively, said screw is enclosed, such as coaxially, by a cylindrical structure, is whereby a potential difference is obtained between said screw and the cylindrical structure. This structure will then resemble a coaxial cable having a centre core—the screw, a dielectric insulator—the material, and a metallic shield—the cylindrical structure.

According to at least one example embodiment, the processing structure comprises a tubular structure which conducts a gas flow for circulating the material inside the vessel. For instance, the tubular structure may form part of a gas-blowing conduit in a fluidised bed vessel. An electromagnetic probe may be used to couple the energy into the tubular structure which will then act as a waveguide.

According to another aspect of the invention, there is provided a use of an existing processing structure, which extends inside a process vessel for processing material contained in the vessel. The processing structure is used as a probe for propagating an electromagnetic signal.

According to yet another aspect of the invention, there is provided a use of a rotatable processing structure, which extends inside a process vessel for processing material contained in the vessel. The processing structure is used as a probe for propagating an electromagnetic signal.

According to a further aspect of the invention, there is provided a use of a tubular processing structure, which extends inside a process vessel and which conducts a gas flow for circulating the material inside the vessel. The processing structure is used as a probe for propagating an electromagnetic signal.

It should be understood that anyone of the above-discussed aspects of the invention encompasses, if compatible, any embodiments or any features described in connection with any of the other above-discussed aspects of the invention.

### BRIEF DESCRIPTION OF THE DRAWINGS

FIG. 1 illustrates at least one example embodiment of the invention, in which an electromagnetic signal may be applied to a rotating screw in a granulator.

FIG. 2 illustrates at least one example embodiment of the invention, in which an electromagnetic signal may be applied at different sections of a rotating screw in a granulator.

FIG. 3 illustrates at least one example embodiment of the invention, in which an electromagnetic signal may be applied to one or two rotating screws in a granulator.

FIG. 4 illustrates at least one example embodiment of the invention, in which an electromagnetic signal may be applied to a gas jet pipe inside a fluidised bed vessel.

FIG. 5 is a schematic of a terminated transmission line.

FIG. 6 illustrates measured complex dielectric constant (permittivity-top, loss factor-bottom) of compacted Microcrystalline Cellulose with moisture content from 1.6% to 32%.

FIG. 7 illustrates an example of Time-Domain Reflectometry (TDR) responses for a probe surrounded by materials with two different dielectric properties. The difference in the properties could be e.g. due to different moisture content, different density or different temperature of the materials.

### DETAILED DESCRIPTION OF THE DRAWINGS

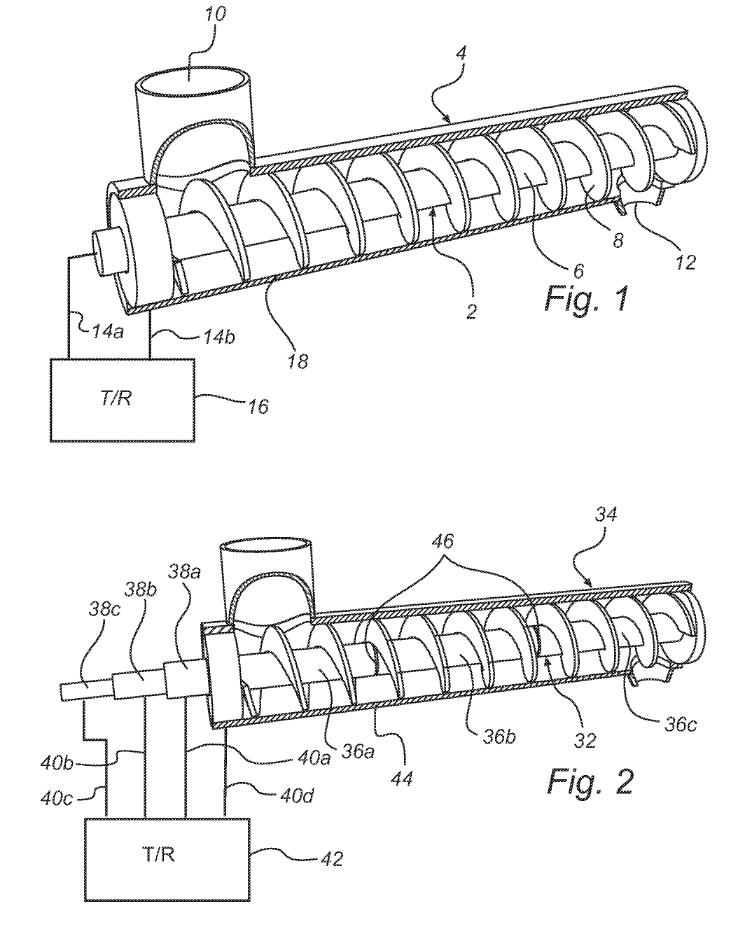

FIG. 1 illustrates at least one example embodiment of the invention, in which an electromagnetic signal may be applied to a rotating screw 2 in a granulator vessel 4. It should however be understood that the following discussion of the example embodiment could be applicable to other elongated processing structures than rotating screws in a granulator vessel. Thus, it may be a processing structure having an elongated extension inside a vessel such as a mixing vessel, drying vessel, coating vessel, etc, enabling information to be extracted along at least a portion of such a vessel.

In FIG. 1, the screw 2 comprises a stem 6 around which a thread-like formation 8 is provided for mixing and feeding material from an inlet port 10 to an outlet port 12. The stem 6 is connected to a motor (not shown) for rotating the stem 6 and thus the thread-like formation 8 of the screw 2. Also, operatively connected to the stem 6 via a first cable 14a is a control unit 16, which includes a signal generator and an electromagnetic transmitter/receiver device. The control unit 16 is also via a second cable 14b connected to the wall 18 of the granulator vessel 4.

In use, an electromagnetic signal will be transmitted from the control unit 16, via the first and second cables 14a, 14b, to the screw 2 and the vessel wall 18. The potential difference between the screw 2 and the vessel wall 18, provided by the two cables 14a, 14b, is typically between about 1 mV and a few Volts. Although, there are various ways to is provide the potential difference, for consistency reasons, it may be suitable to provide a zero or ground potential to the vessel wall 18 via the second cable 14b. Another alternative, instead of having said second cable 14b connected, would be to connect the vessel wall 18 directly to ground.

This structure will then resemble a coaxial cable having a centre core—screw 2, a dielectric insulator—the material, and a metallic shield—the vessel wall 18. In such a way one can propagate electromagnetic energy along the structure. The sensitivity area will be along the length of the screw 2. The electromagnetic signal will travel along the screw 2 and be (partially or totally) reflected by a dielectric change in travelling medium (i.e. having different dielectric constants), such as air pockets, material jamming, an air gap at the end wall or by an end wall itself. The reflected electromagnetic signal will thus return and be received, via the cables 14a, 14b, by the control unit 16. Depending on e.g. time of travel and/or signal amplitude information about the material is obtainable. For instance, some initial small pulses may be indicative of air gaps, while a subsequent large pulse corresponds to the signal traveled along the entire length of the screw 2.

There are other conceivable alternatives to coupling the electromagnetic signal from the control unit 16 via cables 14a, 14b. For instance, wirelessly controlled electromagnetic transmitters and receivers may be applied directly onto the vessel 4 and/or the processing structure (illustrated as a screw 2 in FIG. 1). The control unit would be in wireless operative communication with the transmitters and receivers, thereby enabling the control of the transmission and reception of the signal, and the related analyses, to be performed from a distance.

FIG. 2 illustrates at least one example embodiment of the invention, in which an electromagnetic signal may be applied at different sections of a rotating screw 32 in a granulator vessel 34. In this example embodiment, the rotating screw 32 has three stem sections, namely a proximal section 36a, an intermediate section 36b and a distal section 36c. The proximal section 36a has a connecting portion 38a, which extends out of the granulator vessel 34 and may via a cable 40a be connected to a control unit 42. Likewise, the intermediate section 36b and the distal section 36c have respective connecting portions 38b, 38c which extend out of the granulator vessel 34 and which may via cables 40b, 40c be connected to the control unit 42. The connecting portion 38b of the intermediate section 36b extends concentrically inside and along the connecting portion 38a of the proximal section 36a. The connecting portion 38c of the distal section 36c extends concentrically inside and along the connecting portion 38b of the intermediate section 36b. The control unit 42 comprises a switch (not shown) for selecting one or more of the stem sections 36a, 36b, 36c for transmission of electromagnetic signal. The vessel wall 44 is via a fourth cable 40d connected to the control unit 42. Using the same principle as in the previous example embodiment, however, in this case having the possibility to choose to which stem section(s) the electromagnetic signal is to be applied, local material information around that (or those) stem sections(s) is obtainable.

In the example embodiment of FIG. 2 there are gaps 46 between the intermediate stem section and the two neighbouring sections. Since the dielectric constant of the gaps 46 is different from the dielectric constant of the stem sections 36a, 36b, 36c, an applied electromagnetic signal will at least partly be reflected at the gaps 46. Stem sections 36a, 36b, 36c are suitably electrically isolated between themselves by e.g. an air gap or an isolation ring.

The different conceivable alternatives that were discussed in relation to the example embodiment in FIG. 1 may also be implemented for the example embodiment in FIG. 2.

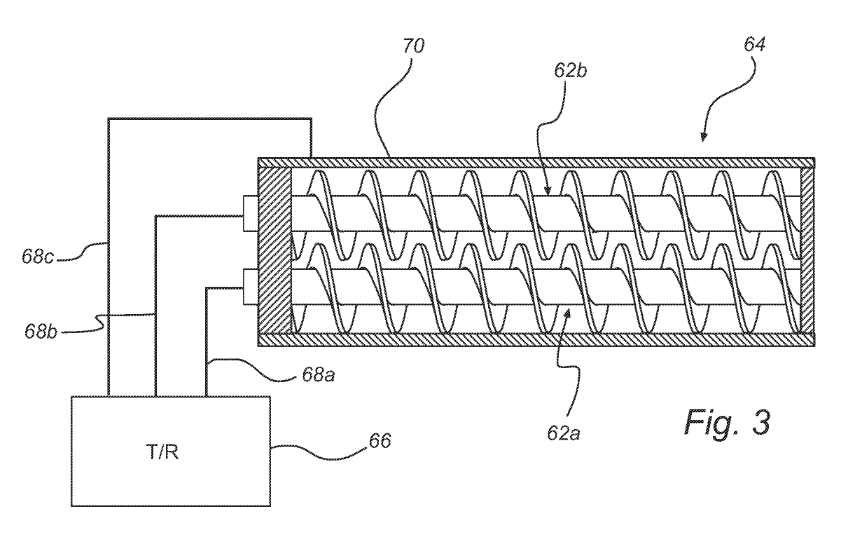

FIG. 3 illustrates at least one example embodiment of the invention, in which an electromagnetic signal may be applied to one or two rotating screws 62a, 62b in a granulator vessel 64. In this example embodiment, the control unit 66 is via cables 68a, 68b, 68c connected to a first screw 62a, a second screw 62b and the vessel wall 70, respectively. Similarly, to the example embodiment illustrated in FIG. 1, an electromagnetic signal may be applied to one of the screws (e.g. the first screw 62a) and providing a potential difference between that screw and the vessel wall 70. Because the screws are located off centre with respect to the geometrical centre axis of the granulator vessel 64, the sensitivity (strength of the electromagnetic field) will be larger close to the wall portion near the screw (e.g. first screw 62a) to which the signal has been applied and smaller around the other screw (e.g. second screw 62b).

Another alternative is to apply different electromagnetic signals having different voltages to the first screw 62a and the second screw 62b, respectively. The vessel wall 70 is not used for coupling in this case. The sensitivity will be greatest along the geometrical centre axis of the vessel 64, i.e. between the two screws 62a, 62b. Thus, it should be understood that by choosing to which structure the electromagnetic signal is applied different areas could be scanned.

The different conceivable alternatives that were discussed in relation to the example embodiments in FIG. 1 and FIG. 2 may also be implemented for the example embodiment in FIG. 3. Additionally, in the example embodiments illustrated in e.g. FIG. 1 and FIG. 3, a receiving unit could be connected to the distal end of the screw stem for detecting the transmitted electromagnetic signal. This could be done instead of or in addition to the reception of the reflected signal as shown in the figures. It should be understood that instead of two screws, the corresponding inventive teaching could be used in a vessel containing three or more screws.

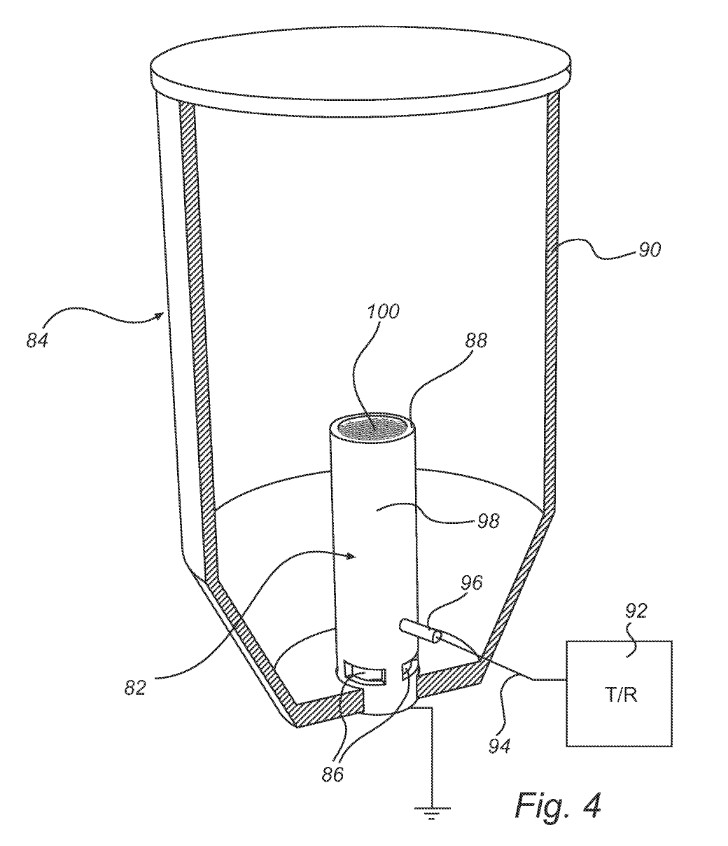

FIG. 4 illustrates at least one example embodiment of the invention, in which an electromagnetic signal may be applied to a gas jet pipe 82 inside a fluidised bed vessel 84. A bed of particles (not shown) is caused to be circulated inside the vessel 84. The particles are drawn into the pipe 82 through inlets 86. Gas, such as air or nitrogen, is provided from a gas supply (not shown) to the bottom of the pipe 82 and is blown upwardly to exit at the upper end 88 of the pipe 82. The particles in the pipe 82 are entrained by the gas jet and become fluidised. Due to gravity, the particles will fall down and become reintroduced into the pipe 82 through the inlets 86. Such a fluidised bed vessel 84 may suitably be used when the particles are to be subjected to e.g. a coating or drying process.

In the example embodiment in FIG. 4, a control unit 92 is via a cable 94 connected to a coupler 96, which protrudes through a hole in the cylindrical pipe wall 98 for coupling energy into the pipe 82. The pipe wall 98 is connected to ground or to the ground wire of cable 94. In use, an electromagnetic signal is transmitted via the coupler 96 into the pipe 82 which will act as a waveguide. A grid 100 (of metal or other suitable material) is provided at the upper end 88 of the pipe 82, having large enough grid holes to allow the particles carried by the jet to exit the pipe 82, and which has the function of at least partly reflecting the electromagnetic wave. The reflected electromagnetic wave is then detected by the control unit 92 for extracting information about the conditions in the pipe 82. In order to obtain a good reflection of the electromagnetic wave, the electromagnetic wavelength is suitably selected based on the dimensions of the pipe 82.

In FIG. 4, it has been illustrated that the pipe 82 will function as a waveguide. However, an alternative would be to use it in the corresponding way as the screw 2 in FIG. 1. Thus, instead of having the pipe wall 98 connected to ground, the vessel wall 90 could be connected to ground. The control unit 92 would via a cable transmit an electromagnetic signal to the pipe wall 98, wherein the potential difference between the pipe wall 98 and the vessel wall 90 would establish an electromagnetic field between the two walls. Thus, instead of analysing the material inside the pipe 82 as illustrated in FIG. 4, it would in the alternative arrangement be possible to analyse the material outside of the pipe 82, or rather the material between the pipe 82 and the vessel wall 90.

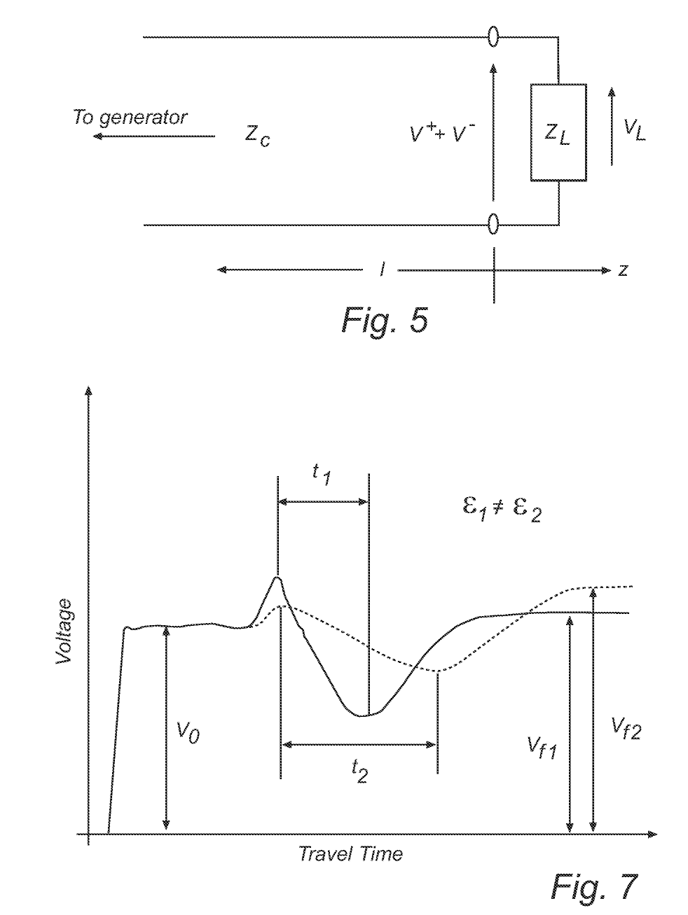

In the following, a theoretical discussion will be presented with reference to FIGS. 5-7. In case of a lossless transmission line with characteristic impedance Z_{C} and terminated with load impedance Z_{L}, the voltage reflection coefficient at the load Γ_{L} is described by the ratio of the reflected from the termination voltage V⁻ to the incident to the termination voltage V⁺. It is given as (see also FIG. 5):

$${Γ}_{L} = \frac{{V}^{-}}{{V}^{+}} = \frac{{Z}_{L} - {Z}_{C}}{{Z}_{L} + {Z}_{C}} \qquad Eq . 1$$

From Eq. 1 one can observe that the amount of reflected or delivered to the load energy depends on both the line and the load impedances. The common cases of interest are when the line is open (Z_{L}=∞), short (Z_{L}=0) or matched load (Z_{L}=Z_{C}), producing reflection coefficients of 1, −1 and 0, respectively. These reflection coefficients are interpreted as an ideal reflection without and with 180° phase change (1 and −1) and as a full energy absorption by the matched load (0). If we define a line propagation constant as γ=α−jβ, where α is the line loss factor and β is the phase constant, the reflection coefficient Γ at any point of the line z<0 (see FIG. 5) is then given as

Γ(z)=Γ_{L}e^{-2jβz}e^{-2αz} Eq.2

which is a function of the load impedance and the line properties.

A complex dielectric constant is given as ∈ₘ=∈′−j∈″, where E′ is the permittivity and represents the ability of the material to store electromagnetic energy, while E″ is the loss factor and represents the loss of electromagnetic energy in the material. Analytical relations between the line propagation constant γ=α−jβ and the dielectric constants of the materials building/surrounding the line could be found and further related to the equivalent line impedance and to the reflection coefficient Γ. Such relationships could be derived from theory and empirically.

The line properties effecting the propagation constant for a transmission line, e.g. twisted pair or a coaxial cable are the geometry of the line as well as the electromagnetic properties of the materials building and surrounding the line. For example for a coaxial cable, such properties are the type of shielding used, diameters and the materials of the centre core, the geometry of the cable and its isolation. In cases of waveguides the propagation is affected by the dielectric properties of the waveguide material, the material filing the waveguide (air or other) and the waveguide geometry and dimensions.

If a two-wire transmission line is considered where materials with different properties surround different sections of the line the equivalent line could be represented by cascade of small sections with characteristic impedance Z_{C}ⁱ and propagation constant γⁱ.

For the characteristic impedance Z_{C}ⁱ one can write:

Z_{C}ⁱ=Z_{P}ⁱ/\sqrt{∈ₘⁱ} Eq.3

where Z_{P}ⁱ is the characteristic impedance of the line surrounded by air and ∈ₘⁱ is the complex dielectric constant of the surrounding material for section i. Z_{P}ⁱ is only a function of the line geometry and could be calculated from electromagnetic theory, simulations or by using calibration materials with known dielectric properties. Any discontinuity of the characteristic impedance due to changes of the dielectric constant will generate reflections according to Eq.1.

The propagation constant γ_{C}ⁱ on the other hand governs the speed and the decay of the propagated signal. It is also a function of the dielectric properties of the surrounding material ∈ₘⁱ and affects the phase delay and the attenuation of the propagated signal. It is given as:

$${γ}_{i} = \frac{j2π f}{c} \sqrt{{ɛ}_{m}^{i}} \qquad Eq . 4$$

where c is the speed of light, f is the frequency used.

As observed from the equations above the dielectric properties of the materials surrounding or inside the transmission lines govern the signal propagation and therefore by obtaining the reflection or the transmission coefficients one could draw conclusions on the material dielectric properties. These dielectric properties are further a function of the material physical state, such as: moisture content, density and temperature.

The dielectric properties of powder materials (commonly used in the pharmaceutical industry) are governed by the amount of moisture contained in them. This is due to the strong interaction of the polar water molecule with electromagnetic energy with frequencies in the radio and the microwave region. Powder mixtures with other liquids will generally also be dominated by the proprieties of the liquid, since the solid-state materials zo used in the pharmaceutical industry are normally quite transparent to the microwave energy. The properties of the water as a function of the frequency f, could be well modelled by a Debye type of equation:

$${ɛ}_{m} ( f ) = [ {ɛ}_{∞} + \frac{{ɛ}_{dc} - {ɛ}_{∞}}{1 + j2π f / {f}_{rel}} ] - \frac{jσ}{2 π f {ɛ}_{0}} \qquad Eq . 5$$

where ∈_{∞} is the permittivity at infinite frequency, ∈_{dc} is the static permittivity, fᵣₑₗ is the relaxation frequency of the material, σ is the material conductivity and ∈₀ is the dielectric permittivity of vacuum. By estimating the above parameters one can fully describe the complex dielectric constant of water. The dielectric constant of other liquids is also readily modelled with such type of equations. Due to the fact that in the pharmaceutical industry it is very common to mix water with the pharmaceutical powder at different process stages or eventually dry to a certain degree of wetness, the Debye type of equations could be used to model the properties of the mixture water/powder (due to the dominant role of the water in terms of dielectric properties). Other more elaborate models could also be applied taking into account e.g. multiple relaxation frequencies corresponding to bound and free water, which could occur for different levels of moisture. The model coefficients could be estimated from measurements of well-known reference samples with e.g. different moisture levels. The set of coefficients as a function of the moisture content will then be used to predict or estimate the moisture level of the powder of interest. Here the influence of the temperature was ignored, but its influence could further be included as a model parameter and the relations obtained through appropriate calibrations if conditions with different temperature are expected.

Another approach to relate the dielectric properties to e.g. moisture content could be to apply mixing formulas utilizing the dielectric constants of e.g. air, water and the dry or wet powder if such mixture is used. Landau and Lifshitz, Looyenga equation, give an example of a mixing formula:

$${( {ɛ}_{mix} )}^{1 / 3} = \frac{{V}_{Wat}}{{V}_{tot}} {( {ɛ}_{Wat} )}^{1 / 3} + \frac{{V}_{pow}}{{V}_{tot}} {( {ɛ}_{Pow} )}^{1 / 3} + \frac{{V}_{Air}}{{V}_{tot}} {( {ɛ}_{Air} )}^{1 / 3} \qquad Eq . 6$$

where V_{Wat} V_{Pow}, V_{Air} and Vₜₒₜ are the volumes of the water, the powder, the air and the total volume of the mixture. Same notations also apply for the dielectric constant. All of the above is also frequency dependent. The dielectric properties of water and air are well known, while the powder (wet or dry) properties could be modelled as explained above. Therefore, if the total dielectric constant ∈ₘᵢₓ is measured for a plurality of frequencies the volumetric ratios of the water, powder and air could be estimated. Obtaining the volumetric ratios and using the density of the water and the dry powder the gravimetric amount of water in the mixture could be estimated.

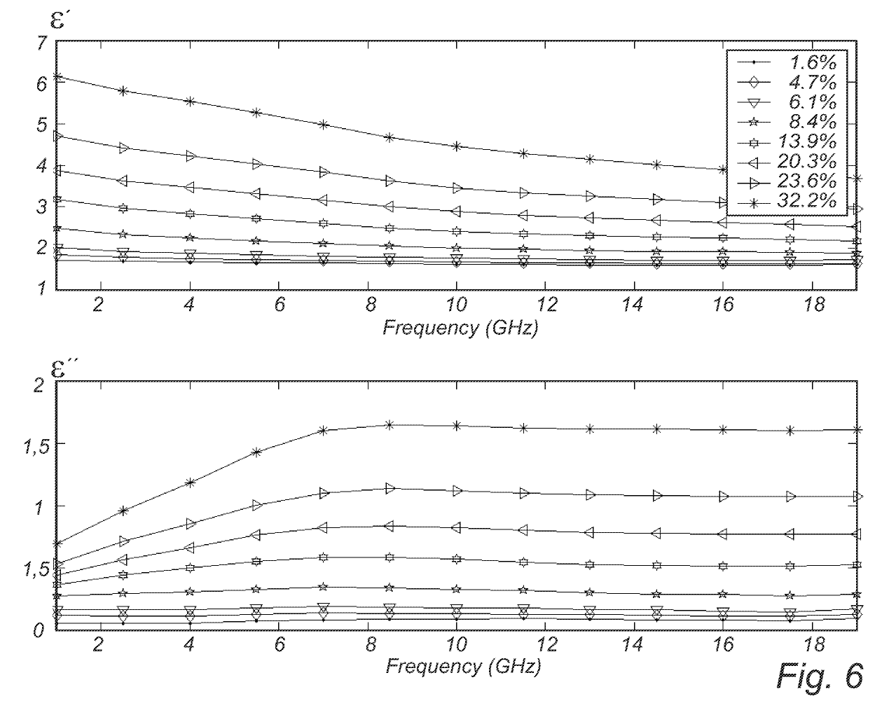

In FIG. 6 an example of the measured dielectric constant of a compacted Microcrystalline Cellulose (MCC) with moisture content from 1.6% to 32% is presented. The frequency range is used 1 to 19 GHz. A Debye type of model could be fit to the measurements and the model coefficients obtained for each moisture level. Further the coefficients could be parameterized to the moisture content. Once measurements of the dielectric constant for a plurality of frequencies for powder with unknown moisture content are obtained, fitting the Debye model and using the calculated coefficients the moisture content is estimated. Density independent ratios of the type: η(f)=∈″(f)/[∈′(f)−1] parameterized to the moisture content could also be utilized if the density variation effects are to be minimized.

In the example herein presented for illustrative purposes, it is demonstrated how at least one embodiment of the invention could be used for retrieval of e.g. moisture content by applying the principles of e.g. Time-Domain Reflectometry (TDR). Although other approaches are applicable and should not limit the generality of the invention.

In the cases of TDR an electromagnetic pulse is propagated along the transmission line terminated by an open or short. The role of this line could be performed by the two screws 62a and 62b in FIG. 3. By using the characteristics of the returned echo (reflected signal), conclusions on the material surrounding the probe could be derived or detection of discontinuities along the line distinguished. If a step pulse (rapid voltage change) is applied on a transmission line the sent signal will reflect back on any impedance discontinuity (Eq.1). By analysing the shape of the returned signal conclusions on the transmission line properties can be drawn. FIG. 7 illustrates the concept and displays examples of waveforms of two received signals when materials with different dielectric properties surround the TDR probe. In the figure, if the reflected pulse has a positive jump it will correspond to a reflection due to discontinuity to higher impedance in the transmission line. Contrary if a negative jump appears in the received reflected signal this will indicate an impedance discontinuity to a lower value. In the figure the first peak in both signals occurs at the impedance discontinuity of the connection at the line input (positive jump indicating higher impedance of the line compared to the standard 50Ω impedance of the connection line), while the second increase in both signals comes from the line's end (open circuited Z_{L}=∞). The drop of the amplitude between the two increases is due to the loss due to the dielectric constant of the surrounding material. The difference of the slope for the two presented cases is due to the different dielectric properties of the surrounding materials.

In cases of two parallel conducting lines using the TDR technique one can measure the velocity of an electromagnetic wave propagated along the transmission line. The velocity v will then be a function of the dielectric properties ∈ₘ=∈′−j∈″ of the surrounding material. The general form of the this relation is given as:

$$ν = \frac{c}{{( \frac{{ɛ}^{′} [ 1 + {( {tan}^{2} δ + 1 )}^{1 / 2} ]}{2} )}^{1 / 2}} \qquad Eq . 7$$

where c is the speed of light in vacuum and tan(δ)=∈″/∈′. It could be assumed that tan(δ)<<1 (true for materials with lower moisture content, see FIG. 6) leading to the relation:

$$ν = \frac{c}{\sqrt{{ɛ}^{′}}} \qquad Eq . 8$$

For a probe with length L from the reflected TDR signal the propagation speed is given as

v=2L/t Eq.9

Combining the above we rewrite:

$${ɛ}^{′} = {( \frac{ct}{2 L} )}^{2} = {( \frac{l}{L} )}^{2} \qquad Eq . 10$$

where l is referred as apparent length. In this way the real part of the effective material dielectric constant is obtained. See FIG. 7 where effectively the time between the reflection from the front end of the probe and the returned echo from the e.g. open ended probe is measured.

If the material surrounding the probe the has a conductivity contribution to the is dielectric constant (see Eq. 5) one can also estimate the conductivity of the surrounding material using the ratio between the voltage amplitude of the excitation voltage V₀ and the voltage value after infinitely long time V_{F}:

$$σ = \frac{1}{C} ( \frac{{V}_{0}}{{V}_{F}} ) \qquad Eq . 11$$

where C is a constant related to the probe configuration and could be determined from theory or empirically. FIG. 7 illustrates the case when the test materials had different contributions form conductivity, represented by the different voltages levels at the end of the measurement time. Using the dielectric properties estimated through Eq.10 and 11 and relating that to models of Eq.5, 6 or FIG. 6 will lead to e.g. the moisture content of the material surrounding the TDR probe.

All of the above estimated dielectric properties are an average over the whole frequency range of the excitation pulse. If the dispersive nature of the dielectric constant is to be considered a more elaborate analyses is necessary. If more advanced modelling is utilized taking into account e.g. the water state additional information could be obtained e.g. about the pharmaceutical process. In order to utilize such spectral analyses the frequency dependent dielectric constant should be obtained. This could be achieved e.g. by converting the time response of the TDR signal to frequency domain and fit a model of the dielectric constant. In this way e.g. the amount of free versus bound water could be estimated.

Same reasoning, but different relations could be applied when the transmission line is a waveguide filled with air or mixture of air and powder e.g. fluidized bed (see e.g. previously discussed FIG. 4). There again the vessel structure is the one guiding the wave propagations and changes of the signals phase and amplitude or time domain response indicated the different dielectric properties of the filling material and thereon indicate about their e.g. moisture content, density and/or temperature.

According to at least one embodiment of the invention, the metal screws inside the vessel could be used as transmission line for the TDR-signal. The transmitter device generates a high-frequency-pulse, which propagates along the transmission line generating an electromagnetic field around the screws acting as a probe. At the end of the screws, the pulse is reflected back to its source. The resulting transit time depends on the dielectric properties of the material surrounding the line. For instance, in a continuous granulation vessel it will be the dielectric properties of the granulated powder, which will affect the returned signal. The dielectric constant of the material surrounding the transmission line is affected by the material moisture, density and temperature. Using the estimated with the TDR technique equivalent dielectric constant (Eq.10) and relating to the results in FIG. 6 one can estimate e.g. the moisture content of the MCC inside the granulator (assuming constant temperature and density inside the vessel). Furthermore, elaborate analyses could be carried out if the spectral information of the TDR signal is utilized and that could be related to models taking into account e.g. the water state inside the mixture (not presented here for the sake of brevity).

Air gaps or jammed material present inside the vessel will also affect the time domain representation of the returned signal. Positive or negative jumps will be present in the signal if discontinuity of the homogeneity of the material distribution inside the vessel is present. Information about material distribution disturbances could be further utilized and used for advanced process control. Observation of the process repeatability could also be a potential application. Further, if models of a profile of the moisture content along the probe are developed, prediction of such profiles could also be envisioned.

1-23. (canceled)

24. A method of analyzing a material contained inside a process vessel, the process vessel having an elongated processing structure extending inside the vessel and adapted to process the material, the method comprising:
applying an electromagnetic signal to the processing structure so that the electromagnetic signal is propagated along the processing structure,
detecting the propagated electromagnetic signal,
determining a value related to the detected signal, and
extracting information about dielectric properties of the material or physical parameters affecting the dielectric properties of the material based on the determined value of the detected signal.

25. The method as claimed in claim 24, comprising:
rotating the elongated processing structure around a longitudinal geometrical axis to mix material inside the vessel, transport material through the vessel, or extrude material from the vessel.

26. The method as claimed in claim 24, comprising:
conducting a gas flow through the processing structure in order to circulate the material inside the vessel.

27. The method as claimed in claim 24, wherein the determined value represents a time of travel of the electromagnetic signal.

28. The method as claimed in claim 24, wherein the determined value represents a distortion of the applied electromagnetic signal.

29. The method as claimed in claim 28, comprising:
determining, in a time domain analysis, a change of amplitude of the electromagnetic signal and, optionally, the time of travel of the electromagnetic signal.

30. The method as claimed in claim 28, comprising:
determining, in a frequency domain analysis, at least one of a change of amplitude or a phase of individual frequencies of the electromagnetic signal.

31. The method as claimed in claim 24, comprising:
detecting the electromagnetic signal after it has been reflected.

32. The method as claimed in claim 24, wherein the electromagnetic signal is applied in the form of an electromagnetic pulse or a continuous electromagnetic wave.

33. The method as claimed in claim 24, wherein the extracted information about dielectric properties of the material is used in obtaining information about at least one of the following physical parameters:
discontinuities in the material distribution, due to air gaps or material jams
moisture content of the material,
temperature of the material, or
density of the material.

34. A method of controlling a manufacturing process, comprising:
analyzing material contained inside a process vessel as claimed in claim 24, and
controlling the manufacturing process based on the extracted information about dielectric properties or other physical parameter affecting the dielectric properties of the material.

35. A method of manufacturing a product, comprising:
inserting material into a process vessel having a processing structure extending inside the vessel and adapted to process the material,
processing the material inside the process vessel,
analyzing the material in accordance with the method claimed in claim 24,
controlling the processing of the material in accordance with the method claimed in claim 34,
removing the processed material from the process vessel, and
providing the processed and removed material in the form of at least one of tablets or powder, wherein the powder is contained in at least one of blisters, capsules, vials, ampules, sachets or inhalers.

36. A device, comprising:
a process vessel configured to contain material to be processed,
an elongated processing structure which extends inside the process vessel and is adapted to process the material contained in the process vessel,
a signal generator operatively connected to the processing structure, the signal generator adapted to apply an electromagnetic signal to the processing structure so that the electromagnetic signal is propagated along the processing structure,
a detector adapted to detect the propagated electromagnetic signal, and
a control unit adapted to determine a value related to the detected signal and to extract information about dielectric properties of the material or physical parameters affecting the dielectric properties of the material based on the determined value of the detected signal.

37. The device as claimed in claim 36, wherein the elongated processing structure is rotatable around a longitudinal geometrical axis for performing at least one of mixing material inside the vessel, transporting material through the vessel, or extruding material from the vessel.

38. The device as claimed in claim 37, wherein the elongated processing structure comprises at least one elongated screw configured to perform at least one of mix, transport or extrude the material.

39. The device as claimed in claim 38, wherein said screw is one of two elongated screws, whereby a potential difference is obtained between the two screws.

40. The device as claimed in claim 38, wherein said screw is enclosed by a cylindrical structure, whereby a potential difference is obtained between said screw and the cylindrical structure.

41. The device as claimed in claim 36, wherein the processing structure comprises a tubular structure which conducts a gas flow for circulating the material inside the vessel.
